(19) United States
(12) Patent Application Publication
(10) Pub. No.: US 2024/0136370 A1
(43) Pub. Date: Apr. 25, 2024

(54) PHOTOELECTRIC CONVERSION APPARATUS, METHOD OF DRIVING THE APPARATUS, SEMICONDUCTOR SUBSTRATE, AND EQUIPMENT

(71) Applicant: CANON KABUSHIKI KAISHA, Tokyo (JP)

(72) Inventors: SHINYA ICHINO, Saitama (JP); HIDEKI IKEDO, Kanagawa (JP)

(21) Appl. No.: 18/483,857

(22) Filed: Oct. 10, 2023

(30) Foreign Application Priority Data
Oct. 14, 2022 (JP) 2022-165393

(51) Int. Cl. H01L 27/146

(52) U.S. Cl. CPC H01L 27/14603; H01L 27/14612; H01L 27/14634

(57) ABSTRACT

A photoelectric conversion apparatus includes an output line and multiple unit pixels. Each of the multiple unit pixels includes a photoelectric conversion element that generates signal electric charge based on incident light, an amplifier transistor that has a gate into which the signal electric charge is input and that outputs a signal based on potential of the gate, a selection transistor with which the amplifier transistor is connected to the output line, and a reset transistor that resets the potential of the gate. The photoelectric conversion apparatus includes a first well on which the selection transistor is provided and a second well on which at least two transistors are provided. The first well is electrically separated from the second well.

### BACKGROUND

### Field of the Disclosure

The disclosure relates to a photoelectric conversion apparatus, a method of driving the photoelectric conversion apparatus, a semiconductor substrate, and equipment.

### Description of the Related Art

Photoelectric conversion apparatuses each including multiple unit pixels are known. The multiple unit pixels each include a photoelectric conversion unit that performs photoelectric conversion of incident light to generate signal electric charge and an amplifier transistor that has a gate through which the signal electric charge is input. The unit pixel further includes a reset transistor that resets the potential of the gate. The gate of the amplifier transistor is electrically connected to the reset transistor. At least part of the transistors in the unit pixel forms one node into which the signal electric charge is input and which is electrically connected.

Japanese Patent Laid-Open No. 2001-160619 discloses a configuration in which a well having a transistor for amplification, which is an amplifier transistor, provided thereon is electrically separated from a well on which other transistors are provided.

The reset transistor into which the signal electric charge is input and which is part of the one node that is electrically connected is provided on the same well as that of a line selection transistor in the configuration disclosed in Japanese Patent Laid-Open No. 2001-160619.

In the configuration disclosed in Japanese Patent Laid-Open No. 2001-160619, the line selection transistor shares the well with the reset transistor, into which the signal electric charge is input and which is one of the transistors forming the one node that is electrically connected. Accordingly, it may sometime be difficult to appropriately set the potential of the well of the selection transistor.

### SUMMARY

One aspect of the technology of the disclosure is a photoelectric conversion apparatus that includes an output line and multiple unit pixels. Each of the multiple unit pixels includes a photoelectric conversion element that generates signal electric charge based on incident light and multiple transistors. The multiple transistors at least include an amplifier transistor that has a gate into which the signal electric charge is input and that outputs a signal based on potential of the gate, a selection transistor with which the amplifier transistor is connected to the output line, and a reset transistor that resets the potential of the gate. The photoelectric conversion apparatus includes a first well on which the selection transistor is provided and a second well on which at least two transistors in the multiple transistors are provided. The first well is electrically separated from the second well.

Another aspect of the technology of the disclosure is a method of driving a photoelectric conversion apparatus including an output line and multiple unit pixels. Each of the multiple unit pixels includes a photoelectric conversion element that generates signal electric charge based on incident light and multiple transistors. The multiple transistors at least include an amplifier transistor that has a gate into which the signal electric charge is input and that outputs a signal based on potential of the gate, a selection transistor with which the amplifier transistor is connected to the output line, and a reset transistor that resets the potential of the gate. The photoelectric conversion apparatus includes a first well on which the selection transistor is provided and a second well on which at least two transistors in the multiple transistors are provided. The method includes setting potential of the second well to first potential during a period in which the selection transistor is in an off state and setting the potential of the second well to second potential different from the first potential during a period in which the selection transistor is in an on state.

Another aspect of the technology of the disclosure is a semiconductor substrate laminated on a component in which a photoelectric conversion element that generates signal electric charge based on incident light is provided. The semiconductor substrate includes an output line and multiple transistors. The multiple transistors at least include an amplifier transistor that has a gate into which the signal electric charge is input and that outputs a signal based on potential of the gate, a selection transistor with which the amplifier transistor is connected to the output line, and a reset transistor that resets the potential of the gate. The semiconductor substrate includes a first well on which the selection transistor is provided and a second well on which at least two transistors in the multiple transistors are provided. The first well is electrically separated from the second well.

Further features of the present disclosure will become apparent from the following description of embodiments with reference to the attached drawings.

### BRIEF DESCRIPTION OF THE DRAWINGS

FIG. 1 is a block diagram illustrating an entire configuration of a photoelectric conversion apparatus.

FIG. 2 illustrates an equivalent circuit of a unit pixel.

FIG. 3 illustrates a configuration of the unit pixels in a plan view.

FIG. 4 is a cross-sectional view of the unit pixel.

FIG. 5 is a diagram illustrating a driving timing of the photoelectric conversion apparatus.

FIG. 6 illustrates potential of each node in a selection transistor.

FIG. 7 illustrates an equivalent circuit of a unit pixel.

FIG. 8 illustrates a configuration of the unit pixels in a plan view.

FIG. 9 is a cross-sectional view of the unit pixel.

FIG. 10 is a block diagram illustrating an entire configuration of a photoelectric conversion apparatus.

FIG. 11 illustrates an equivalent circuit of a unit pixel.

FIG. 12 is a cross-sectional view of the photoelectric conversion apparatus.

FIG. 13 illustrates a configuration of part of the unit pixels in a plan view.

FIG. 14 is a cross-sectional view of part of the unit pixel.

FIG. 15 is a diagram illustrating a driving timing of the photoelectric conversion apparatus.

FIG. 16 illustrates an equivalent circuit of a unit pixel.

FIG. 17 illustrates a configuration of part of the unit pixels in a plan view.

FIG. 18 is a cross-sectional view of part of the unit pixel.

FIG. 19 illustrates a configuration of part of the unit pixels in a plan view.

FIG. 20 illustrates a configuration of part of the unit pixels in a plan view.

FIG. 21A to FIG. 21C illustrate the configurations of equipment.

### DESCRIPTION OF THE EMBODIMENTS

The respective embodiments will herein be described with reference to the drawings.

Each embodiment described below focuses on an imaging apparatus as an example of a photoelectric conversion apparatus. However, each embodiment is not limited to the imaging apparatus and is applicable to another example of the photoelectric conversion apparatus. For example, each embodiment is applicable to, for example, a focusing apparatus (an apparatus for focus detection, distance measurement using Time Of Flight (TOF), or the like) or a photometric apparatus (an apparatus for measurement of the amount of incident light or the like).

Semiconductor regions, the conductivity types of wells, and dopant to be injected, which are described in the embodiments below, are only examples and are not limited to the semiconductor regions, the conductivity types of wells, and the dopant described in the embodiments. The conductivity types of wells and the dopant, which are described in the embodiments, may be appropriately changed and the semiconductor regions and the potentials of the wells may be appropriately changed in accordance with the change of the conductivity types of wells and the dopant.

The conductivity types of transistors described in the embodiments below are only examples and are not limited to the ones described in the embodiments. The conductivity types described in the embodiments may be appropriately changed and the potentials of the gates, the sources, and the drains of the transistors may be appropriately changed in accordance with the change of the conductivity types.

For example, in the case of a transistor that is operated as a switch, the low level and the high level of the potential to be supplied to the gate may be reversed with respect to the ones described in the embodiments in accordance with the change of the conductivity types. In addition, the conductivity types of the semiconductor regions described in the embodiments below are only examples and are not limited to the ones described in the embodiments. The conductivity types described in the embodiments may be appropriately changed and the potentials of the semiconductor regions may be appropriately changed in accordance with the change of the conductivity types.

### First Embodiment

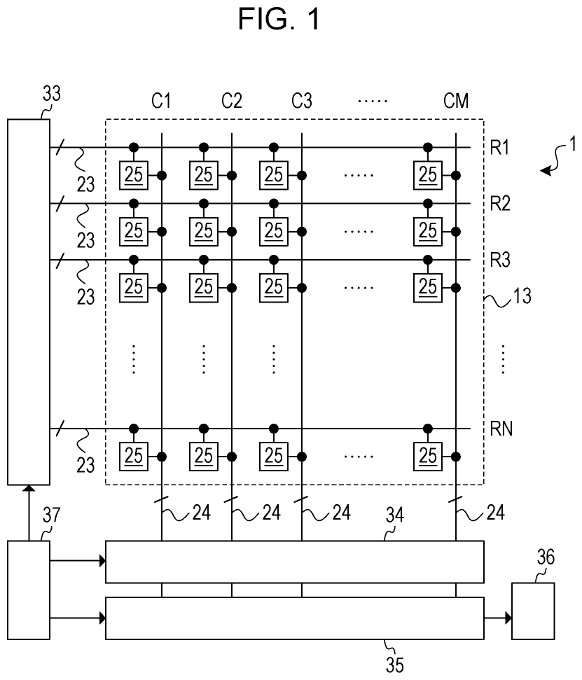

A photoelectric conversion apparatus and a method of driving the photoelectric conversion apparatus according to a first embodiment will now be described with reference to FIG. 1 to FIG. 6.

FIG. 1 is a block diagram illustrating the photoelectric conversion apparatus according to the first embodiment. A photoelectric conversion apparatus 1 according to the first embodiment includes a pixel region 13, a vertical drive circuit 33, a column signal processor 34, a horizontal drive circuit 35, an output circuit 36, and a system controller 37.

Multiple rows and multiple columns are arrayed in the pixel region 13. The pixel region 13 includes multiple unit pixels 25 that output pixel signals corresponding to the amounts of received light. Each unit pixel 25 includes a photoelectric conversion unit that generates and accumulates signal electric charge based on incident light. The unit pixels 25 of N-number lines and M-number columns, which are composed of an R1-st line to an RN-th line and a C1-st column to a CM-th column, are illustrated in FIG. 1.

A control line 23 extends in the horizontal direction (the direction along the pixel lines) on each line of the pixel region 13. Each control line 23 is connected to the multiple unit pixels 25 arranged on the same line and forms a signal line common to the multiple unit pixels 25. Each control line 23 may include multiple signal lines. The control lines 23 are connected to the vertical drive circuit 33.

An output line 24 extends in the vertical direction (the direction along the pixel columns) on each column of the pixel region 13. Each output line 24 is connected to the multiple unit pixels 25 arranged on the corresponding column and forms a signal line common to the multiple unit pixels 25. Each output line 24 may include multiple output lines.

The output lines 24 are connected to the column signal processor 34.

The vertical drive circuit 33 is a control circuit having a function to receive a control signal supplied from the system controller 37, to generate a control signal for driving the unit pixels 25, and to supply the generated control signal to the unit pixels 25 via the control lines 23. The signals read out from the unit pixels 25 in unit of lines are input into the column signal processor 34 via the output lines 24.

The column signal processor 34 includes multiple column circuits (not illustrated) provided for the corresponding multiple output lines 24. Each of the multiple column circuits includes a processing circuit and a signal holding circuit. The processing circuit has a function to perform certain signal processing to the pixel signal output through the corresponding output line 24. The signal processing performed by the processing circuit includes, for example, amplification, correction through correlated double sampling (CDS), and analog-to-digital conversion (AD conversion). The signal holding circuit includes a memory for holding the pixel signal processed in the processing circuit.

The horizontal drive circuit 35 is a control circuit having a function to receive a control signal supplied from the system controller 37, to generate a control signal for reading out the pixel signal from the column signal processor 34, and to supply the pixel signal to the column signal processor 34. The horizontal drive circuit 35 sequentially scans the column circuits of the respective columns in the column signal processor 34 and causes the column circuits to supply the pixel signals that are held in the column circuits to the output circuit 36.

The output circuit 36 includes an external interface circuit and outputs the signal processed in the column signal processor 34 to the outside of the photoelectric conversion apparatus 1. The external interface circuit in the output circuit 36 is not particularly limited.

The system controller 37 is a control circuit that generates control signals for controlling the operations of the vertical drive circuit 33, the column signal processor 34, and the horizontal drive circuit 35 and supplies the generated control signals to the respective functional blocks.

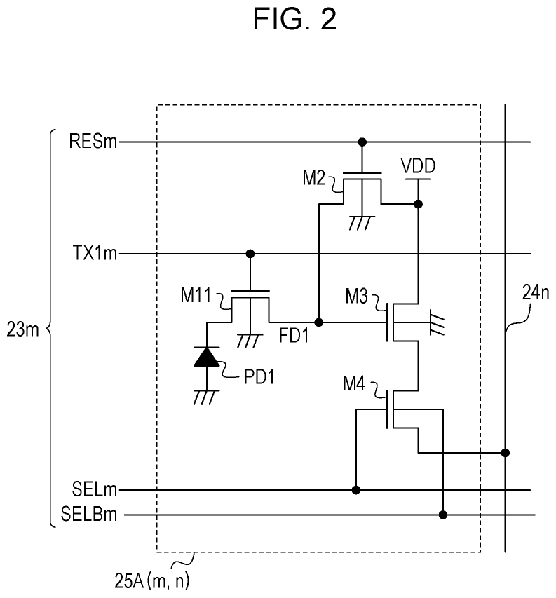

FIG. 2 is a first equivalent circuit diagram of the unit pixel 25 in the first embodiment. A unit pixel 25A (m, n) arrayed on the m-th line and the n-th column is illustrated in FIG. 2. Here, m denotes an integer from 1 to M and n denotes an integer from 1 to N. The other unit pixels 25 composing the pixel region 13 may include the same circuit configuration as that of the unit pixel 25A (m, n).

The unit pixel 25A (m, n) includes a photoelectric conversion element PD1, a transfer transistor M11, a reset transistor M2, an amplifier transistor M3, and a selection transistor M4.

The photoelectric conversion element PD1 is, for example, a photodiode. The photoelectric conversion element PD1 performs photoelectric conversion of the incident light and accumulates the electric charge. The number of the photoelectric conversion elements in each unit pixel 25A is not limited to one. The photoelectric conversion element PD1 may be a photoelectric conversion film including at least one of an organic thin film and an inorganic thin film.

The transfer transistor M11 is provided to transfer the signal electric charge (may be sometimes simply referred to as electric charge) generated by the photoelectric conversion element PD1 to a floating diffusion region on a semiconductor substrate.

The floating diffusion region, the gate of the amplifier transistor M3, and one of the source and the drain of the reset transistor M2 compose a floating diffusion (FD) node. The FD node further includes metal lines with which the floating diffusion region is connected to the gate of the amplifier transistor M3. The FD node is an electrically common node including the amplifier transistor M3 and the reset transistor M2. A control signal TX1m is supplied from the vertical drive circuit 33 to the gate of the transfer transistor M11 via a control line 23m of the m-th line. When the control signal TX1m is at the high level, the electric charge that is generated and accumulated in response to light incident on the photoelectric conversion element PD1 is transferred to the FD node via the transfer transistor M11. The FD node is composed of lines and electrodes of the drain of the transfer transistor M11, the source of the reset transistor M2, and the gate of the amplifier transistor M3.

The electric charge transferred from the photoelectric conversion element PD1 is held in the FD node. The electric charge held in the FD node is converted into voltage. In other words, the voltage at the FD node has a value corresponding to the amount of the electric charge transferred from the photoelectric conversion element PD1.

The reset transistor M2 resets the potential of the FD node to voltage corresponding to power supply voltage VDD. In other words, the reset transistor M2 resets the potential of the gate of the amplifier transistor M3 to the voltage corresponding to the power supply voltage VDD. A control signal RESm is supplied from the vertical drive circuit 33 to the gate of the reset transistor M2 via the control line 23m. When the control signal RESm is at the high level, the potential of the FD node is reset to the voltage corresponding to the power supply voltage VDD. When the control signal RESm is at the high level and the control signal TX1m is at the high level, the voltage of the photoelectric conversion element PD1 is capable of being reset to the voltage corresponding to the power supply voltage VDD. However, it is not necessary to set both the control signal RESm and the control signal TX1m to the high level. For example, the signal electric charge of the photoelectric conversion element PD1 is transferred to the FD when the control signal TX1m is at the high level. Then, the signal electric charge of the photoelectric conversion element PD1 is reset also when the control signal RESm is at the high level to reset the FD.

The amplifier transistor M3 supplies the signal to an output line 24n of the n-th column via the selection transistor M4. The power supply voltage VDD is applied to the drain of the amplifier transistor M3. The source of the amplifier transistor M3 is connected to the drain of the selection transistor M4. The amplifier transistor M3 composes a source follower along with a current source included in the column signal processor 34. When the selection transistor M4 is in a conductive state (an on state), the amplifier transistor M3 outputs the signal corresponding to the voltage of the FD node. This sets the signal level of the output line 24 to the level of the signal output from the amplifier transistor M3.

The selection transistor M4 is provided between the amplifier transistor M3 and the output line 24n.

A control signal SELm is supplied from the vertical drive circuit 33 to the gate of the selection transistor M4 via the control line 23m. When the control signal SELm makes the transition to the high level, the selection transistor M4 supplies the output from the amplifier transistor M3 to the output line 24n.

The selection transistor M4 has a resistance component (hereinafter referred to as on resistance) depending on voltage (V_{GS}) between the gate and the source of the selection transistor M4 in the conductive state. The on resistance is varied with the floating diffusion region of each unit pixel 25 and the potential of the FD node to reduce linearity of the signal. This will be described in detail below.

A well W_{SEL} on which the selection transistor M4 is arranged is electrically connected to the control line 23m. In other words, the potential set by a control signal SELBm is applied to the well W_{SEL} on which the selection transistor M4 is arranged. A well (a second well) on which the reset transistor M2 is arranged is connected to ground potential. In contrast, the potential of the well W_{SEL} (a first well) of the selection transistor M4 is controlled independently of well potential of the other pixel transistors. Specifically, the potential of the well W_{SEL} of the selection transistor M4 has a period different from that of the potential of the well on which the reset transistor M2 is arranged in the photoelectric conversion apparatus of the first embodiment.

While the photoelectric conversion apparatus is operating, the potential of the well W_{SEL} of the selection transistor M4 may be constantly differentiated from the potential of the well on which the reset transistor M2 is arranged. Alternatively, the potential of the well W_{SEL} of the selection transistor M4 may be differentiated from the potential of the well on which the reset transistor M2 is arranged only during a partial period. Other elements may be further arranged on the well on which the reset transistor M2 is arranged. For example, the photoelectric conversion element PD1, the transfer transistor M11, and the amplifier transistor M3 may be further arranged on the well on which the reset transistor M2 is arranged.

The structure of the unit pixel 25 will now be described, focusing on the structure of the well W_{SEL}. An example is described below in which the photoelectric conversion element PD1, the transfer transistor M11, and the amplifier transistor M3 are further arranged on the well on which the reset transistor M2 is arranged.

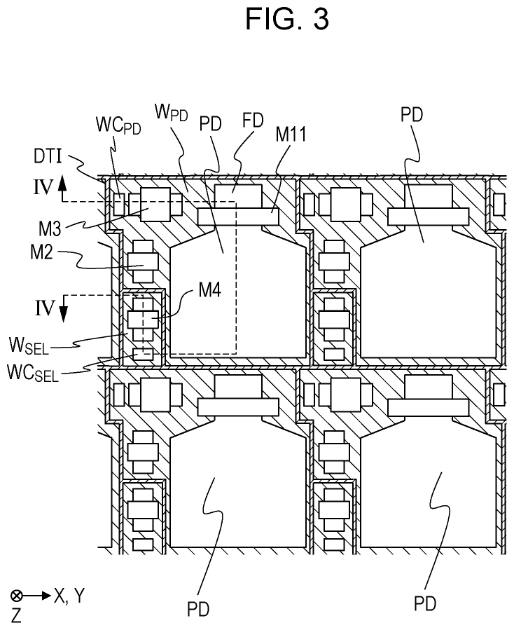

FIG. 3 illustrates the structure of the unit pixel 25 of the first embodiment.

The four unit pixels 25A of two lines and two columns in a plan view are illustrated in FIG. 3. Each of the four unit pixels 25A illustrated in FIG. 3 corresponds to the equivalent circuit in FIG. 2 and the respective elements composing the unit pixel 25A have the common configuration. Referring to FIG. 3, the horizontal direction indicates the X or Y direction and the depth direction with respect to the page indicates the Z direction. In this specification, the “plan view” means viewing of a plane parallel to the plane at the side at which the gates of the transistors of the semiconductor substrate are arranged from the direction orthogonal to the parallel plane. In other words, the “plan view” means viewing of a plane parallel to a first surface of the semiconductor substrate from the Z direction or the −Z direction in FIG. 3.

The unit pixel 25A is separated into at least two regions by an insulating separator (deep trench isolation (DTI)) in a plan view. The selection transistor M4 is arranged in one region and a photoelectric conversion element PD is arranged in the other region. The insulating separator DTI is arranged between the selection transistor M4 and the photoelectric conversion element PD in a plan view. The insulating separator DTI is arranged so as to surround the selection transistor M4.

The insulating separator DTI has a function to separate the well W_{SEL} including a region serving as the channel of the selection transistor M4 from a well W_{PD} on which the reset transistor M2 is arranged. The photoelectric conversion element PD is further arranged on the well W_{PD}. Although the wells W_{PD} on which the photoelectric conversion elements PD are arranged in the respective pixels are also separated with the insulating separator DTI in FIG. 3, the wells W_{PD} in the respective pixels may not be separated with the insulating separator DTI.

The well W_{SEL} is electrically connected to the control signal SELBm via a well contact WC_{SEL} of the well W_{SEL}. The well W_{PD} is electrically connected to the ground potential via a well contact WC_{PD} arranged on the well W_{PD}. The transfer transistor M11, the reset transistor M2, and the amplifier transistor M3 are arranged on the well W_{PD}. In other words, the insulating separator DTI is arranged between the selection transistor M4, and the reset transistor M2 and the amplifier transistor M3. FD denotes a floating diffusion region to which the signal electric charge of the photoelectric conversion element PD is transferred and is part of the FD node.

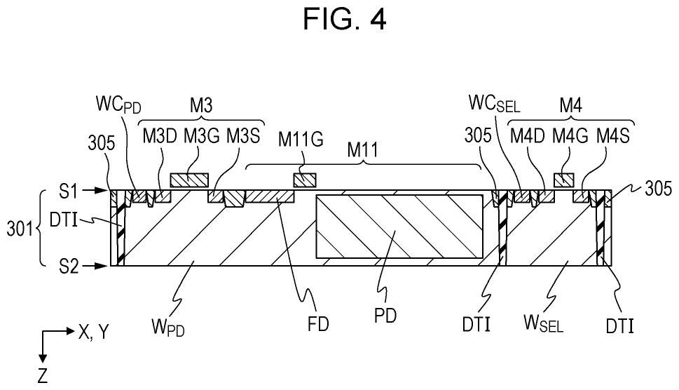

FIG. 4 is a schematic cross-sectional view taken along the IV-IV line in FIG. 3. Of a semiconductor substrate 301, a surface at the side at which an electrode M3G serving as the gate of the amplifier transistor M3 is arranged is referred to as a first surface S1 and a surface opposed to the first surface S1 is referred to as a second surface S2. The direction from the first surface S1 to the second surface S2 is the Z direction. Light is incident from the second surface S2 in FIG. 4. The second surface S2 may be referred to as a rear face and the first surface S1 may be referred to as a front face. The semiconductor substrate is, for example, a silicon substrate. The silicon substrate is typically a substrate mostly containing Si among the elements. Alternatively, a silicon on insulator (SOI) substrate may be used as another example of the semiconductor substrate. The light may be incident from the first surface S1.

The sources and the drains of the pixel transistors including the FD, the transfer transistor M11, the reset transistor M2, the amplifier transistor M3, and the selection transistor M4 each include an N-type semiconductor region in which N-type impurities are diffused. The electrode M3G serving as the gate of the amplifier transistor M3, an electrode M11G serving as the gate of the transfer transistor M11, and an electrode M4G serving as the gate of the selection transistor M4 are arranged on the first surface S1. The well contact WC_{SEL} of the well W_{SEL} and the well contact WC_{PD} of the well W_{PD} are arranged in the semiconductor substrate 301.

The well contact WC_{SEL} and the well contact WC_{PD} each include a P-type semiconductor region in which P-type impurities are diffused. The well contact WC_{SEL} and the well contact WC_{PD} compose part of the first surface S1 of the semiconductor substrate 301. An element isolator 305 is arranged in each of the regions between the multiple pixels and the region between the photoelectric conversion element PD and the pixel transistor region of one pixel. The element isolator 305 has a shallow trench isolation (STI) structure or a local oxidation of Si (LOCOS) structure. As illustrated in FIG. 4, the insulating separator DTI passes through the semiconductor substrate 301 in the Z direction. Specifically, the insulating separator DTI extends in the Z direction (the depth direction) from the first surface S1 to the second surface S2 of the semiconductor substrate 301. In the semiconductor substrate 301, the well W_{SEL} including the region serving as the channel of the selection transistor M4 is electrically separated from the well W_{PD} including the photoelectric conversion element PD with the insulating separator DTI.

According to the first embodiment, the well W_{SEL} is electrically separated from the photoelectric conversion element PD with the insulating separator DTI passing through the semiconductor substrate 301. This electrical separation is considered as a substantially insulated state. In other words, the well W_{SEL} is electrically separated from the well WPB with the insulating separator DTI. This electrical separation is considered as a substantially insulated state. Although the electrical separation with the insulating separator DTI is described in the configuration illustrated in FIG. 4, the well W_{SEL} may be electrically separated from the well W_{PD} using electrical separation using PN junction. Accordingly, the electrical separation method of the wells is not limited to the separation method described in the first embodiment. However, the electrical separation with the insulating separator DTI is desirable because of greater electrical separation, compared with the electrical separation using the PN junction.

As described above, electrically separating the potential of the well W_{SEL} of the selection transistor M4 from the well of the other pixel transistors enables the potential determined by the control signal SELBm through the control line 23m to be supplied to the well W_{SEL}.

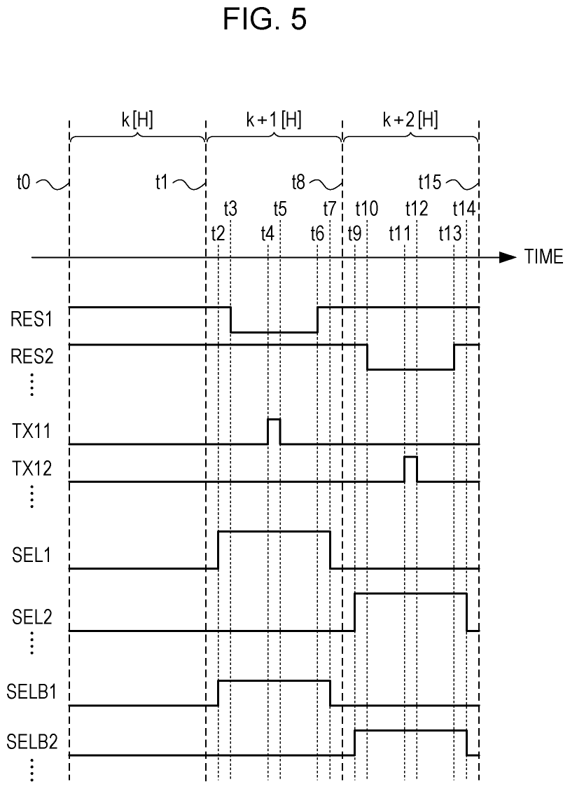

The method of driving the photoelectric conversion apparatus in the first embodiment will now be described FIG. 5.

FIG. 5 is a driving timing chart for describing readout of signals in the unit pixel 25 in the first embodiment. The timing chart of control signals RES1 to RES2, TX11 to TX12, and SEL1 to SEL2, which are supplied from the vertical drive circuit 33 to unit pixels 25(1, n) to 25(2, n) during horizontal scanning periods k to k+2 (k is an integer), is illustrated in FIG. 5. The respective control signals are in an active state at the high level and are in a non-active state at the low level. Control signals SELB1 to SELB2 denote the potentials to be supplied to the well W_{SEL} of the selection transistor M4. The potential at the high level or the low level is supplied to the well W_{SEL} via the well contact WC_{SEL}.

No pixel signal is read out during a period from a time t0 to a time t1. The control signals RES1 to RES2 are kept at the high level during this period. Accordingly, the on state of the reset transistor M2 of each of the unit pixels 25(1, n) to 25(2, n) is kept and a reset operation of the FD node is continued. The control signals TX11 to TX12, SEL1 to SEL2, and SELB1 to SELB2 are kept at the low level. At this time, potential (first potential), such as negative potential, corresponding to the low level, is applied to the well W_{SEL} of the selection transistor M4.

A period from the time t1 to a time t8 corresponds to a readout period of the unit pixel 25(1, n). The readout of the signals from the photoelectric conversion element PD in the unit pixel 25(1, n) is performed during the period from the time t1 to the time t8. At the time t2, the control signal SEL1 makes the transition from the low level to the high level and the selection transistor M4 in the unit pixel 25(1, n) is in the on state. As a result, the unit pixel 25(1, n) is electrically connected to the output line 24n.

At the time t2, the control signal SELB1 makes the transition from the low level to the high level and the potential, such as the ground potential, corresponding to the high level is applied to the well W_{SEL} of the selection transistor M4 in the unit pixel 25(1, n). The potential corresponding to the high level means potential (second potential) relatively higher than the potential applied to the well W_{SEL} during the period from the time t0 to the time t1.

At the time t3, the control signal RES1 makes the transition from the high level to the low level and the reset transistor M2 in the unit pixel 25(1, n) is in the off state. As a result, the reset state of the FD node in the unit pixel 25(1, n) is cleared. Then, the potential of the FD node is decreased to certain potential because of coupling with the gate of the reset transistor M2. The voltage of the FD node, which is statically determined after the reset transistor M2 is in the off state, is used as reset voltage of the FD node in the unit pixel 25(1, n).

The signal corresponding to the reset voltage of the FD node in the unit pixel 25(1, n) is supplied to the output line 24n via the amplifier transistor M3 and the selection transistor M4. Then, the signal is processed in the column signal processor 34 and is read out as an N signal of the unit pixel 25(1, n).

At the time t4, the control signal TX11 makes the transition from the low level to the high level and the transfer transistor M11 in the unit pixel 25(1, n) is in the on state. As a result, the electric charge accumulated in the photoelectric conversion element PD in the unit pixel 25(1, n) during a certain exposure period is transferred to the FD node in the unit pixel 25(1, n).

The signal corresponding to the amount of the electric charge transferred from the photoelectric conversion element PD to the FD node in the unit pixel 25(1, n) is supplied to the output line 24n via the amplifier transistor M3 and the selection transistor M4. The voltage of the output line 24n is varied with the amount of the electric charge that has occurred in the photoelectric conversion element PD.

At the time t5, the control signal TX11 makes the transition from the high level to the low level and the transfer transistor M11 in the unit pixel 25(1, n) is in the off state. As a result, the transfer period of the electric charge from the photoelectric conversion element PD to the FD node in the unit pixel 25(1, n) is terminated. The signal supplied from the unit pixel 25(1, n) to the output line 24n is processed in the column signal processor 34 after the statical determination and is read out as an S signal of the photoelectric conversion element PD in the unit pixel 25(1, n).

At the time t6, the control signal RES1 makes the transition from the low level to the high level and the reset transistor M2 in the unit pixel 25(1, n) is in the on state. As a result, the reset operation of the FD node in the unit pixel 25(1, n) is started.

At the time t7, the control signal SEL1 makes the transition from the high level to the low level and the selection transistor M4 in the unit pixel 25(1, n) is in the off state. As a result, the unit pixel 25(1, n) is not electrically connected to the output line 24n.

At the time t7, the control signal SELB1 makes the transition from the high level to the low level and the potential of the well W_{SEL} of the selection transistor M4 in the unit pixel 25(1, n) is set to the potential corresponding to the low level.

As described above, during the horizontal scanning period from the time t1 to the time t8, the readout of the signals in the unit pixel 25(1, n) is performed.

Then, a horizontal scanning period from the time t8 to a time t15 corresponds to a readout period of the unit pixel 25(2, n). The readout of the signals from the photoelectric conversion element PD of the unit pixel 25(2, n) is performed during the period from the time t8 to the time t15. The respective control signals are driven in the same manner as in the previous horizontal scanning period described above. The scanning is sequentially performed to read out the signals from the entire pixel region.

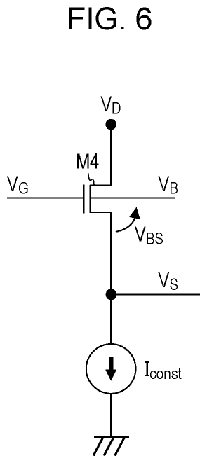

The influence of the potential of the well W_{SEL} of the selection transistor M4 on the linearity of the signal will now be described in detail with reference to FIG. 6. The drain corresponding to the input of the selection transistor M4 and the source corresponding to the output of the selection transistor M4 will be described here, focusing on the linearity of the input and output signals.

The output signal from the selection transistor M4 is generally calculated according to Equation (1):

V_{S}=V_{D}−R_{ON}·I_{const} Formula 1

Here, Vₛ denotes the potential of the source of the selection transistor M4, V_{D} denotes the potential of the drain of the selection transistor M4, R_{ON} denotes the on resistance of the selection transistor M4, and I_{const} denotes constant current determined by the current source included in the column signal processor 34.

The on resistance R_{ON} of the selection transistor M4 is generally calculated according to Equation (2):

$${R}_{ON} = \frac{L}{W \cdot μ \cdot {C}_{OX} \cdot ( {V}_{GS} - {V}_{TH} )} \qquad Formula 2$$

Here, L denotes the gate length of the selection transistor M4, W denotes the gate width of the selection transistor M4, μ denotes the mobility of channeled electron of the selection transistor M4, C_{OX} denotes the capacity per unit area of the selection transistor M4, and V_{TH} denotes threshold voltage of the selection transistor M4.

As indicated in Equation (1), voltage drop due to the constant current I_{const} and the on resistance R_{ON} is desirably constant in order to keep the linearity with respect to the input and output of the selection transistor M4. However, as indicated in Equation (2), the on resistance R_{ON} has a variable of voltage V_{GS} between the gate and the source of the selection transistor M4. Accordingly, the on resistance R_{ON} of the selection transistor M4 is varied with variation in the potential of the output line 24n in response to the variation in the potential of the FD node. In other words, the on resistance R_{ON} is varied with the amount of signal occurring at the photoelectric conversion element PD to cause the reduction in the linearity.

For suppression of the reduction in the linearity in the readout of the signals (in the on state), the threshold voltage V_{TH} of the selection transistor M4 is desirably designed to be low in order to decrease the on resistance R_{ON} of the selection transistor M4. In contrast, the selection transistor M4 has a function to electrically separate the amplifier transistor M3 from the output line 24n in the off state in which the signal in the low level is supplied from the control line 23m. In other words, in consideration of the off state, the threshold voltage V_{TH} is desirably designed to be high in order to suppress leakage current. Accordingly, it is effective to decrease the threshold voltage V_{TH} in the on state while keeping the threshold voltage V_{TH} in the off state in order to suppress the reduction in the linearity.

The threshold voltage V_{TH} of the selection transistor M4 is generally calculated according to Equation (3):

V_{TH}=V_{TH0}+γ(\sqrt{−—V_{BS}+2Ø_{F}}−\sqrt{2Ø_{F}}) Formula 3

Here, V_{BS} denotes voltage between the well and the source of the selection transistor M4, V_{TH0} denotes threshold voltage of the selection transistor M4 when the voltage V_{BS} is 0 V, 2Φ_{F} denotes surface potential, and γ denotes a substrate effect parameter.

As indicated in Equation (3), the threshold voltage V_{TH} of the selection transistor M4 has a variable of the voltage V_{BS} between the well and the source of the selection transistor M4. This is equivalent to the fact that well potential V_{B} is a variable of the threshold voltage V_{TH} when the potential of the source of the selection transistor M4 is constant. Through the use of this, the unit pixel 25 of the first embodiment controls the well potential V_{B} of the selection transistor M4 in response to the control signal SELBm from the control line 23m to vary the effective threshold voltage V_{TH} between in the on state and in the off state. Accordingly, it is possible to suppress the leakage current of the selection transistor M4 when the selection transistor M4 is in the off state. In addition, it is possible to achieve the output of the pixel signal with the reduction in the linearity being suppressed when the selection transistor M4 is in the on state.

More specifically, the well potential V_{B} of the well W_{SEL}, which is applied in the on state of the selection transistor M4, is set to a value relatively higher than that of the well potential V_{B} applied to the well W_{SEL} in the off state. For example, the ground potential may be set as the high level and the negative potential may be set as the low level. Under this condition, it is possible to decrease the threshold voltage V_{TH} in the on state to keep the effective threshold voltage V_{TH} in the off state, which is equivalent to that in a case in which the well potential V_{B} of the well W_{SEL} is connected to the ground potential. The well potential V_{B} of the well W_{SEL}, which is applied in the on state of the selection transistor M4, may be equal to the potential of the well W_{PD}. In other words, the well potential V_{B} of the well W_{SEL} is lower than the potential of the well W_{PD} during the period in which the selection transistor M4 is in the off state. The well potential V_{B} of the well W_{SEL}, which is applied in the on state of the selection transistor M4, may be higher than the potential of the well W_{PD}.

The well potential V_{B} of the well W_{SEL} is varied in the first embodiment. As another example, a configuration may be adopted in which the well potential V_{B} of the well W_{SEL} is set to a value higher than the potential of the well W_{PD} across the entire period in which the photoelectric conversion apparatus is operating to suppress the reduction in the linearity of the pixel signal output from the selection transistor M4.

It is important in the first embodiment to realize the configuration in which the well W_{SEL} on which the selection transistor M4 is provided is electrically separated from the well W_{PD}. This enables the potential of the well W_{SEL} to be set independently of the well W_{PD}. With this configuration, it is possible to achieve at least one of the suppression of the leakage current of the selection transistor M4 and the acquisition of the pixel signal with the reduction in the linearity being suppressed.

Attention is focused here on the well potential V_{B} in the on state of the selection transistor M4, which is relatively higher than the well potential V_{B} in the off state. Since the effective threshold voltage V_{TH} is decreased, as indicated in Equation (3), when the well potential V_{B} is increased, the on resistance R_{ON} is decreased. Accordingly, as indicated in Equation (1), the decrease in the on resistance R_{ON} suppresses the reduction in the linearity to enable the acquisition of the high-quality image.

The high level of the well potential V_{B} of the selection transistor M4, supplied from the control signal SELBm, is set to the ground potential and the low level thereof is set to the negative potential in the first embodiment. However, the well potential V_{B} is not limited to the above ones. As another example, the well potential V_{B} may be set to positive potential. In this case, it is desirable to set the well potential V_{B} within a range in which the voltage between the well and the source and the voltage between the well and the drain are not directed to the forward direction.

The low level of the control signal SELm is desirably set to the potential equal to that of the low level of the control signal SELBm. More specifically, when the low level of the control signal SELBm is set to the negative potential, the low level of the control signal SELm is desirably set to the same negative potential.

The photoelectric conversion apparatus of the first embodiment is capable of deceasing the on resistance of the selection transistor M4 to enable the acquisition of the high-quality image.

The relationship of the potentials is described in the first embodiment on the assumption that the selection transistor M4 is the N-type transistor. As described above, the potentials may be appropriately changed in accordance with the change of the conductivity types of the transistors in the description of the specification. In other words, when the selection transistor M4 is the P-type transistor, the well potential V_{B} of the well W_{SEL}, which is applied in the on state of the selection transistor M4, is set to a value relatively lower than the well potential V_{B} applied to the well W_{SEL} in the off state.

The configuration is exemplified in the first embodiment in which the well W_{PD} on which the reset transistor M2 is provided is electrically separated from the well W_{SEL} on which the selection transistor M4 is provided. With this configuration, it is possible to achieve at least one of the suppression of the leakage current of the selection transistor M4 and the acquisition of the pixel signal with the reduction in the linearity being suppressed.

The configuration of the unit pixel 25 may be appropriately varied. For example, the transfer transistor M11 and the floating diffusion region may be omitted. In other words, the contact may be provided in a partial region of the photoelectric conversion element PD and the contact may be connected to the gate of the amplifier transistor M3. Also with this configuration, the potential of the well W_{SEL} may be set independently of the well on which the reset transistor is provided. Although the multiple transistors composing the FD node in this case are the reset transistor M2 and the amplifier transistor M3, a transistor to switch the capacitance value of the FD node may be further provided.

### Second Embodiment

A second embodiment will now be described, focusing on the points different from the first embodiment.

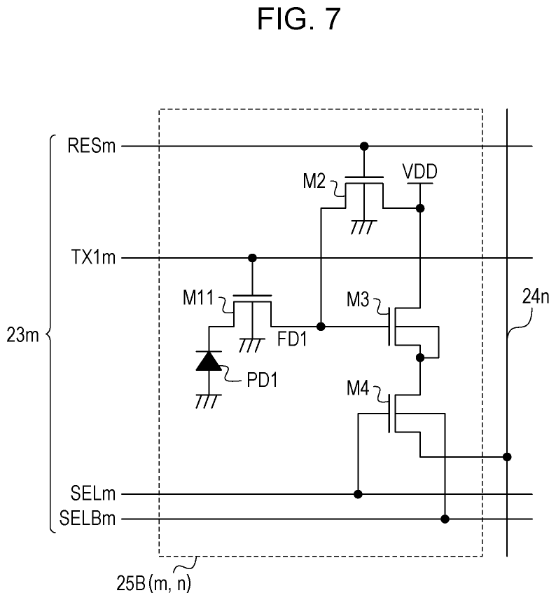

FIG. 7 is a second equivalent circuit diagram of the unit pixel 25 in the second embodiment. A unit pixel 25B (m, n) arrayed on the m-th line and the n-th column is illustrated in FIG. 7. The unit pixel 25B differs from the unit pixel 25A in that a well W_{AMP} on which the amplifier transistor M3 is arranged is electrically separated from the well W_{SEL} and the well W_{PD} and is electrically connected to the source of the amplifier transistor M3.

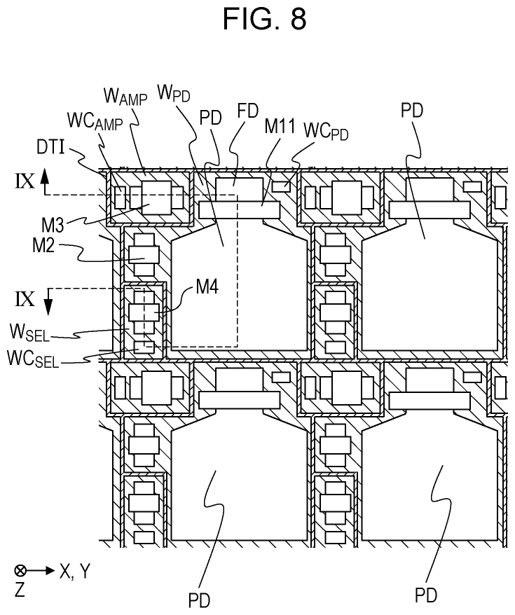

FIG. 8 illustrates a layout including the unit pixel 25B corresponding to the equivalent circuit diagram in FIG. 7 and illustrates the four unit pixels 25B of two lines and two columns in a plan view.

The second embodiment differs from the first embodiment in that the unit pixel 25B is separated into at least three regions with the insulating separator DTI in a plan view. The selection transistor M4 is arranged in a first region, the photoelectric conversion element PD is arranged in a second region, and the amplifier transistor M3 is arranged in a third region. The insulating separator DTI is arranged so as to surround the selection transistor M4 and the amplifier transistor M3. The insulating separator DTI has a function to separate the well W_{SEL} including the region serving as the channel of the selection transistor M4, the well W_{PD} on which the photoelectric conversion element PD is arranged, and the well W_{AMP} including a region serving as the channel of the amplifier transistor M3 from each other.

The well W_{AMP} is electrically connected to the source of the amplifier transistor M3 via a well contact WC_{AMP} arranged on the well W_{AMP}. The transfer transistor M11 and the reset transistor M2 are arranged on the well W_{PD}. In other words, the insulating separator DTI is arranged between the selection transistor M4, the reset transistor M2, and the amplifier transistor M3.

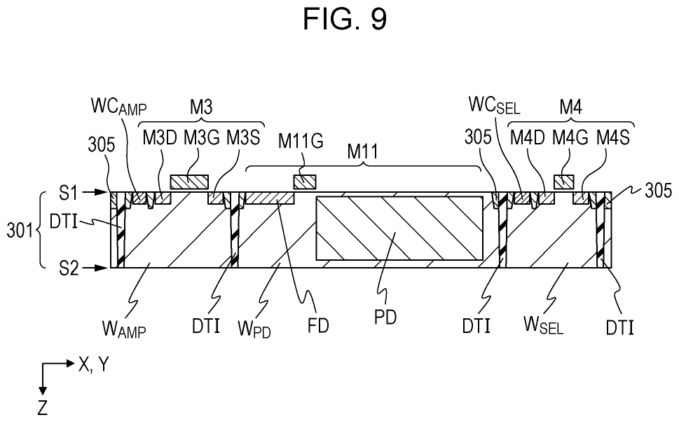

FIG. 9 is a schematic cross-sectional view taken along the IX-IX line in FIG. 8. The unit pixel 25B differs from the unit pixel 25A in that the insulating separator DTI separating the well W_{AMP} of the amplifier transistor M3 from the well W_{PD} is added. The insulating separator DTI is configured so as to pass through the semiconductor substrate 301. The well contact WC_{AMP} of the well W_{AMP} is arranged in the semiconductor substrate 301 and is composed of the P-type semiconductor region in which P-type impurities are diffused. The well contact WC_{AMP} composes part of the first surface S1 of the semiconductor substrate 301.

In the unit pixel 25B, the well W_{AMP} is electrically separated from the well W_{SEL} and the well W_{PD}. Since the source of the amplifier transistor M3 is electrically connected to the well W_{AMP}, the voltage V_{BS} between the well and the source of the amplifier transistor is substantially fixed to 0 V. Accordingly, the threshold voltage V_{TH} of the amplifier transistor M3 due to a substrate bias effect is capable of being substantially kept constant. Consequently, the linear line of the pixel signal is less likely to be non-linear, compared with a case in which the well potential Vg of the amplifier transistor M3 is connected to the ground potential.

As described above, in the unit pixel 25B, it is possible to further suppress the reduction in the linearity of the signal due to the substrate bias effect of the amplifier transistor M3, in addition to the suppression of the reduction in the linearity by the selection transistor M4.

As described above, according to the second embodiment, the well W_{SEL} of the selection transistor M4 is separated from the well W_{PD} on which the photoelectric conversion element PD is arranged and the potential of the well W_{SEL} is controlled in the on state and the off state of the selection transistor M4 to further suppress the reduction in the linearity of the signal.

### Third Embodiment

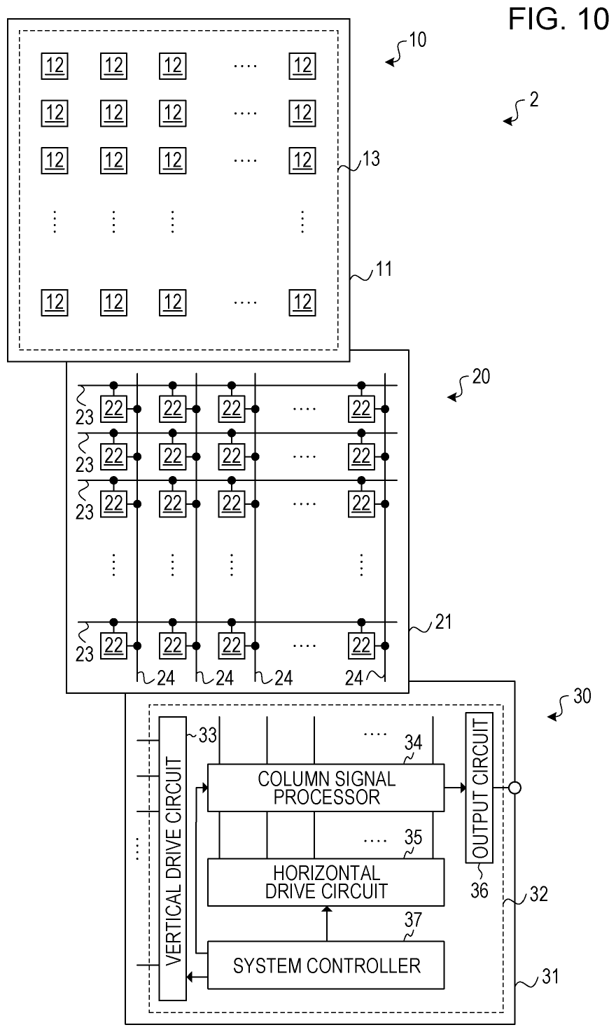

A photoelectric conversion apparatus and a method of driving the photoelectric conversion apparatus according to a third embodiment will now be described with reference to FIG. 10 to FIG. 20. FIG. 10 is a block diagram of the photoelectric conversion apparatus in the third embodiment.

As illustrated in FIG. 10, a photoelectric conversion apparatus 2 includes three components: a first component 10, a second component 20, and a third component 30. The photoelectric conversion apparatus 2 is a multilayer photoelectric conversion apparatus composed by bonding the three components. The first component 10, the second component 20, and the third component 30 are laminated in this order.

The first component 10 has a first semiconductor substrate 11. Multiple sensor portions 12 performing the photoelectric conversion are provided on the first semiconductor substrate 11. The multiple sensor portions 12 are arrayed in multiple lines and multiple columns in the pixel region 13 of the first component 10. Each of the multiple sensor portions 12 includes the photoelectric conversion element PD and the transfer transistor M11. The multiple sensor portions 12 output the signal electric charge corresponding to the amount of incident light. The first component 10 includes various films, such as an insulating film, provided at the side of a second semiconductor substrate 21, viewed from the first semiconductor substrate 11.

The second component 20 has the second semiconductor substrate 21. Read-out circuits 22 that output the pixel signals based on the electric charge output from the sensor portions 12 are provided on the second semiconductor substrate 21. The read-out circuit 22 includes the pixel transistors. The second component 20 includes the multiple control lines 23 extending in the horizontal direction and the multiple output lines 24 extending in the vertical direction. The control lines 23 are connected to the vertical drive circuit 33. Each of the output lines 24 is connected to the read-out circuits 22 arranged in the vertical direction to form a signal line common to the read-out circuits 22. The output lines 24 are connected to the column signal processor 34. The second component 20 includes various films, such as an insulating film, provided at at least one of the side of the first semiconductor substrate 11 and the side of a third semiconductor substrate 31, viewed from the second semiconductor substrate 21.

The third component 30 has the third semiconductor substrate 31. A logic circuit 32 processing the pixel signals is provided on the third semiconductor substrate 31. The logic circuit 32 includes, for example. the vertical drive circuit 33, the column signal processor 34, the horizontal drive circuit 35, the output circuit 36, and the system controller 37. The third component 30 includes various films, such as an insulating film, provided at the side of the second semiconductor substrate 21, viewed from the third semiconductor substrate 31.

The first component 10 is laminated on the second component 20 by bonding the insulating film of the first component 10 to the insulating film of the second component 20.

The second component 20 is laminated on the third component 30 by bonding the insulating film of the second component 20 to the insulating film of the third component 30.

As described above, the photoelectric conversion apparatus of the third embodiment has the configuration in which the three components described above with reference to FIG. 10 are laminated. Among the components included in the unit pixel, the photoelectric conversion element PD is provided on the first semiconductor substrate 11 and the pixel transistors excluding the transfer transistor are provided on the second semiconductor substrate 21 in the third embodiment. This enables the space in which the pixel transistors are arranged to be easily ensured to further decrease the pixel pitch. Accordingly, it is possible to realize the photoelectric conversion apparatus appropriate for miniaturization.

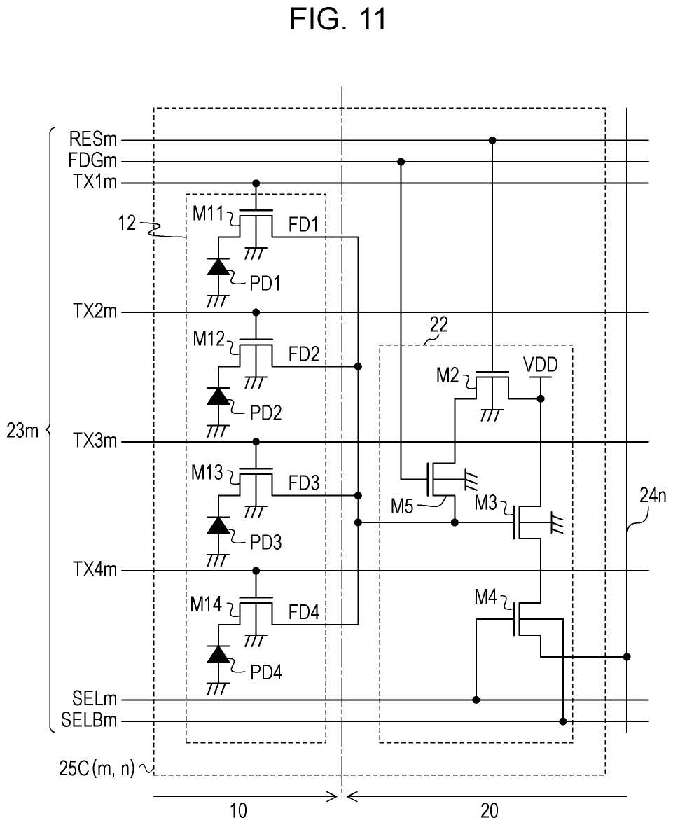

FIG. 11 is a first equivalent circuit diagram of the unit pixel 25 in the third embodiment. A unit pixel 25C (m, n) arrayed on the m-th line and the n-th column is illustrated in FIG. 11. The unit pixel 25C differs from the unit pixel 25A on the equivalent circuit diagram in that the unit pixel 25C has a configuration in which signals from four photodiodes PD1 to PD4 are transferred to FD1 to FD4 via transfer transistors M11 to M14 corresponding to the photodiodes PD1 to PD4, respectively, and the signals are read out by the common read-out circuit 22. Although the configuration is adopted in FIG. 11 in which the signals from the four photodiodes PD1 to PD4 are read out by one read-out circuit 22, the photoelectric conversion elements PD of an arbitrary number may be connected to one read-out circuit 22.

An FD capacitance switching transistor M5 is arranged between the source of the reset transistor M2 and the FD nodes in the configuration in FIG. 11. A control signal FDGm is supplied from the vertical drive circuit 33 to the gate of the FD capacitance switching transistor M5. The capacitance value of the FD capacitance is capable of being varied by switching between the on state and the off state of the FD capacitance switching transistor M5 to switch the conversion efficiency. In other words, the FD capacitance switching transistor M5 is a transistor that switches between connection and non-connection of the capacitance to the gate of the amplifier transistor M3. This capacitance is of the FD capacitance switching transistor M5 in the third embodiment. However, the capacitance is not limited to this example and, for example, a capacitance element may be provided on an electrical path between the reset transistor M2 and the FD capacitance switching transistor M5. It is sufficient for this capacitance element to have the capacitance, such as a metal-insulator-metal (MIM) capacitance, a metal oxide metal (MOM) capacitance, a metal oxide silicon (MOS) capacitance, or a metal insulator silicon (MIS) capacitance. The MIM capacitance has a structure in which an insulating layer is sandwiched between multiple metal (including polysilicon) layers. The MOM capacitance has a structure in which an oxide film (including an oxynitride film), such as a silicon oxide film, is sandwiched between multiple metal (including polysilicon) layers. The MOS capacitance has a structure in which an oxide film (including an oxynitride film), such as a silicon oxide film, is sandwiched between a semiconductor layer and a metal (including polysilicon) layer in the silicon substrate. The MIS capacitance has a structure in which an insulating film is sandwiched between a semiconductor layer and a metal (including polysilicon) layer in the silicon substrate.

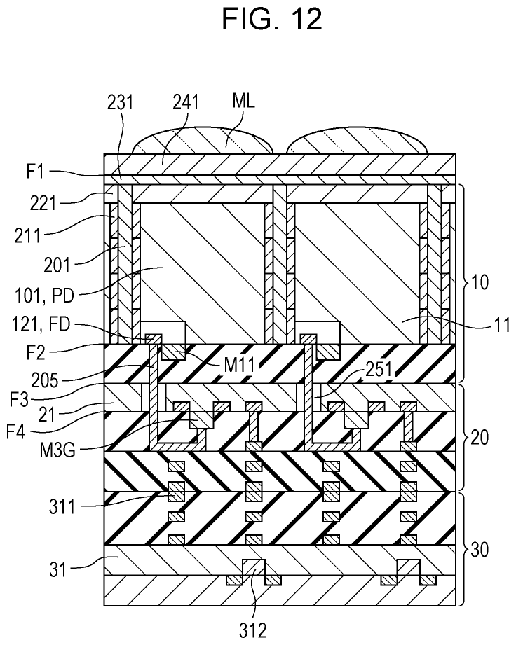

FIG. 12 is a cross-sectional view of the photoelectric conversion apparatus of the third embodiment. This cross-sectional view is taken along a line passing through the photoelectric conversion element PD and the gate of the transfer transistor M11 in the first component 10, the second component 20, and the third component 30. The photoelectric conversion element PD includes an N-type semiconductor region 101. The two sensor portions 12 appearing on one cross section, among the four sensor portions 12, are illustrated in the cross-sectional view in FIG. 12.

The gate of the transfer transistor M11 controls the conductive state between the photoelectric conversion element PD and a semiconductor region 121, which is a region in the FD. The semiconductor region 121 is the N-type semiconductor region. A pixel separator 201 is provided between the multiple semiconductor regions 101 to electrically separate the multiple semiconductor regions 101 from each other. The pixel separator 201 may include an insulating portion made of silicon oxide or the like or may be a semiconductor region forming a potential barrier.

Typically, the pixel separator 201 is a semiconductor region using the electric charge having a polarity opposite to that of the signal electric charge accumulated in the photoelectric conversion element PD as a main carrier. A pixel serration layer 211 is provided between the pixel separator 201 and the semiconductor region 101. The pixel serration layer 211 has a role of reducing dark current particularly when the pixel separator 201 is provided as the insulating portion. The semiconductor region 121, which is the FD, is connected to the electrode M3G serving as the gate of the amplifier transistor M3 via a conductor 205. The conductor 205 mainly contains metal, such as tungsten or copper. The conductor 205 is formed so as to pass through an insulator 251 that separates the second semiconductor substrate 21. The insulator 251 electrically separates the multiple read-out circuits 22 from each other. The insulator 251 is provided so as to pass through the semiconductor substrate 21 from a third surface F3, which one surface of the second semiconductor substrate 21, to a fourth surface F4, which is the other surface thereof opposed to the third surface F3. The conductor 205 is a through electrode passing through the insulator 251.

The first semiconductor substrate 11 has a first surface F1 at the light incident surface side and a second surface F2 opposed to the first surface F1. A semiconductor region 221 is the P-type semiconductor region provided in a region at the first surface F1 side (the light incident surface side) of the semiconductor region 101. A fixed electric charge film 231 is provided on the first surface F1 of the first semiconductor substrate 11. The dark current flowing into the semiconductor region 101 is reduced with the semiconductor region 221 and the fixed electric charge film 231.

A microlens ML leads light to the semiconductor region 101. A planarized layer 241 is provided between the microlens ML and the fixed electric charge film 231. A color filter may be further provided for each of the multiple sensor portions 12 to perform color separation.

The first component 10, the second component 20, and the third component 30 are laminated. The second component 20 is provided between the first component 10 and the third component 30. A transistor 312 is provided in the third semiconductor substrate 31 of the third component 30. The second component 20 is electrically connected to the third component 30 via connection portions 311. The connection portions 311 are made of metal. Typically, the connection portions 311 mainly contain copper. The connection portions 311 further contain barrier metal (for example, titanium or nickel) for suppressing the diffusion of copper.

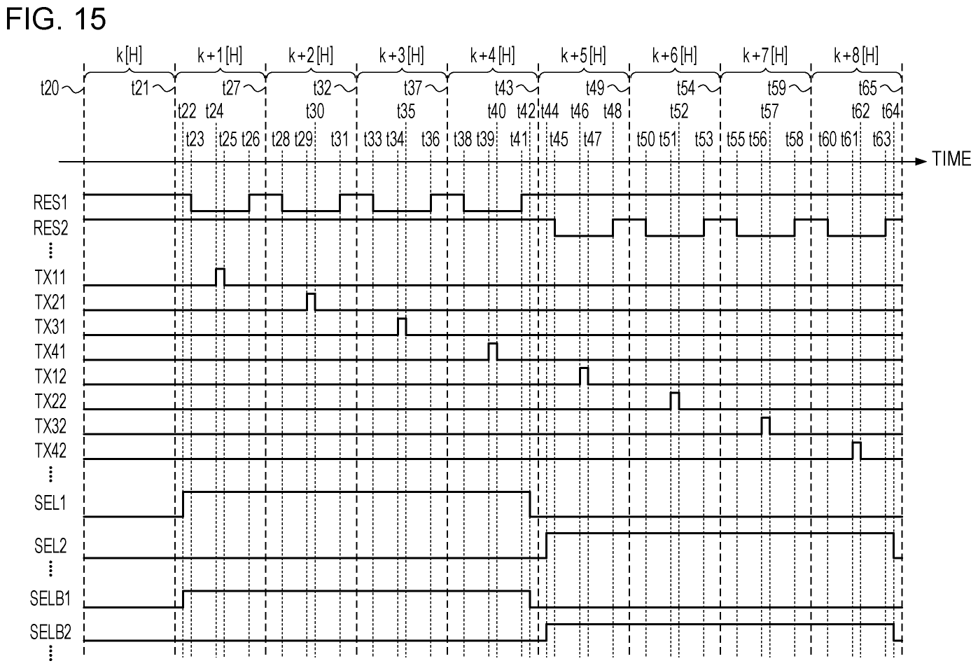

The method of driving the photoelectric conversion apparatus in the third embodiment will be described below with reference to FIG. 15. With the method of driving the photoelectric conversion apparatus in the third embodiment, the reduction in the linearity of the signal, which can be caused by the variation of the on resistance of the selection transistor M4 in accordance with the potential of the floating diffusion region of each pixel, is capable of being suppressed.

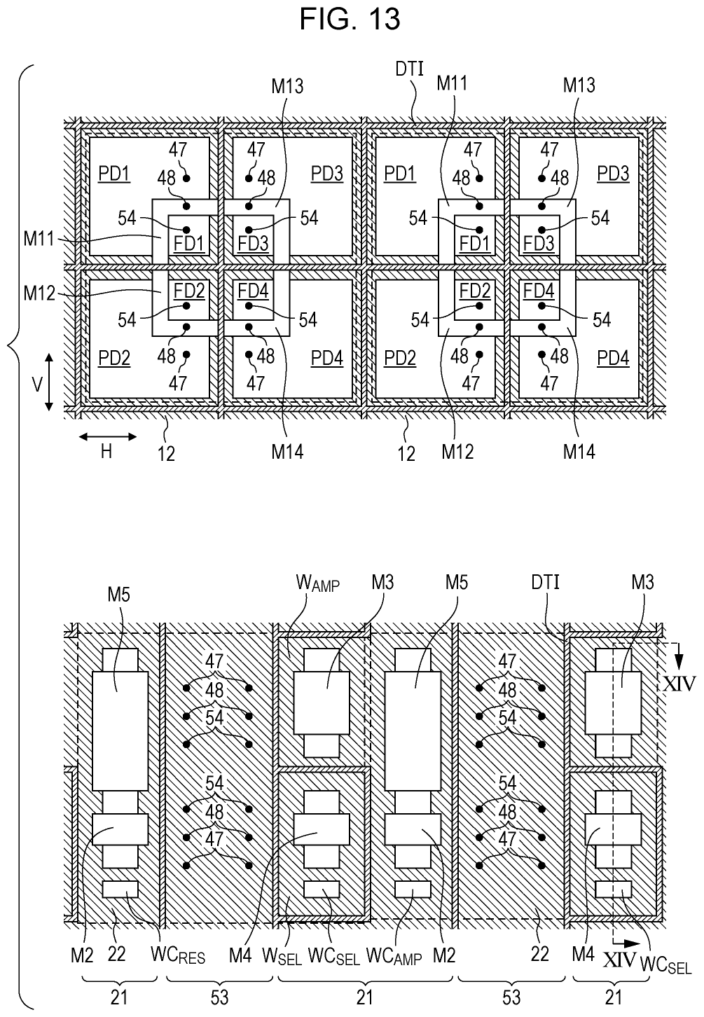

FIG. 13 illustrates a layout including the unit pixel 25C corresponding to the equivalent circuit diagram in FIG. 11 and illustrates the two unit pixels 25C of one line and two columns in a plan view. The two unit pixels 25C illustrated in FIG. 13 each correspond to the equivalent circuit diagram illustrated in FIG. 11 and the respective elements composing the unit pixel 25C have the common configuration. An upper diagram in FIG. 13 illustrates the layout of the first component 10 in FIG. 10 in a plan view. A lower diagram in FIG. 13 illustrates the layout of the second component 20 in FIG. 10 in a plan view. The first component 10 is electrically connected to the second component 20 via multiple through electrodes 47, multiple through electrodes 48, and multiple through electrodes 54. The through electrodes 54 illustrated in FIG. 13 are part of the conductor 205 illustrated in FIG. 12.

As illustrated in FIG. 13, the second component 20 is composed of the second semiconductor substrate 21 and the region of an insulating layer 53 including the through electrodes 54 and so on in a plan view. The pixel transistors included in the read-out circuit 22 are arranged in the region of the second semiconductor substrate 21.

The amplifier transistor M3 is arranged on the well common to the reset transistor M2 and the FD capacitance switching transistor M5, which are arranged in the read-out circuit 22 adjacent to the amplifier transistor M3 at the right side in a plan view.

The insulating separator DTI is arranged so as to surround the selection transistor M4. Accordingly, the well W_{SEL} of the selection transistor M4 is electrically separated from the well W_{AMP} including the other pixel transistors.

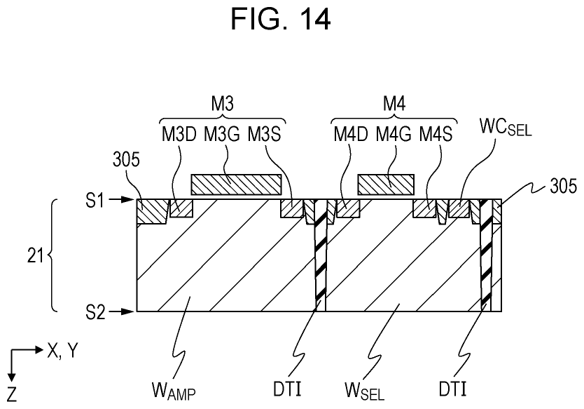

FIG. 14 is a schematic cross-sectional view taken along the XIV-XIV line in FIG. 13. Referring to FIG. 14, the well W_{SEL} on which the selection transistor M4 is arranged is electrically separated from the well W_{AMP} on which the amplifier transistor M3 and so on are arranged with the insulating separator DTI.

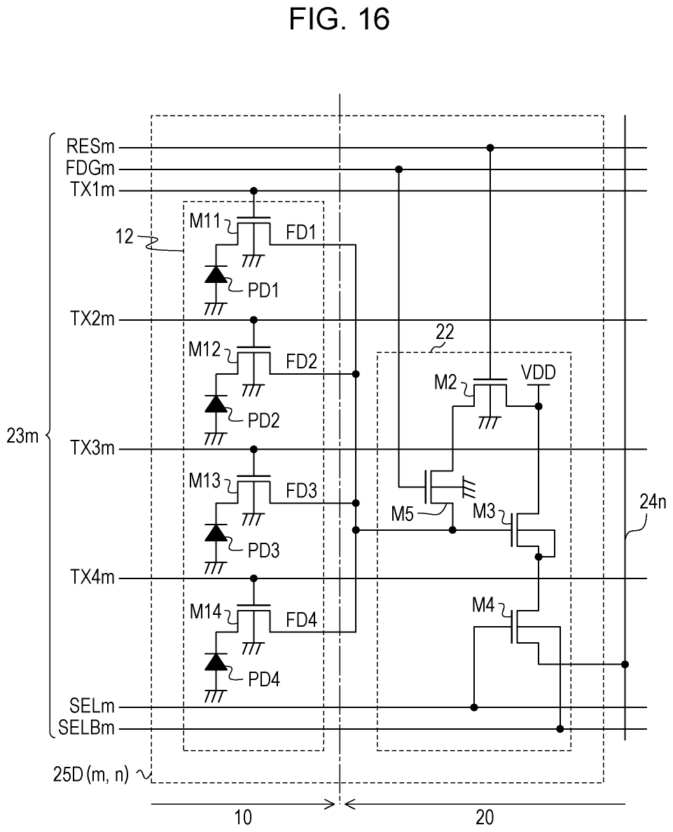

FIG. 16 is a second equivalent circuit diagram of the unit pixel 25 in the third embodiment. A unit pixel 25D (m, n) arrayed on the m-th line and the n-th column is illustrated in FIG. 16. The unit pixel 25D differs from the unit pixel 25C in that the well W_{AMP} on which the amplifier transistor M3 is arranged is electrically separated from the well W_{SEL} and a well W_{RES} and is electrically connected to the source of the amplifier transistor M3.

FIG. 15 is a driving timing chart for describing readout of signals in the unit pixel 25 in the third embodiment. The control signals RES1 to RES2 to be supplied from the vertical drive circuit 33 to the unit pixels 25(1, n) to 25(2, n) during horizontal scanning periods k to k+8(k is an integer) are illustrated in FIG. 15. In addition, control signals TX11 to TX42, the control signals SEL1 to SEL2, and the control signals SELB1 and SELB2, which are to be supplied from the vertical drive circuit 33 to the unit pixels 25(1, n) to 25(2, n), are illustrated in FIG. 15.

A period from a time t21 to a time t43 corresponds to the readout period from the unit pixel 25(1, n). The readout of the signals from the photoelectric conversion elements PD1 to PD4 in the unit pixel 25(1, n) is performed during the period from the time t21 to the time t43. The signal of one PD is read out during each horizontal scanning period and the signals of the four PDs are read out during the four horizontal scanning periods. A period from the time t22 to the time t42 is a period in which the unit pixels 25 in the line including the unit pixel 25(1, n) are selected. The control signal SEL1 and the control signal SELB1 are fixed to the high level during the period from the time t22 to the time t42.

A period from the time t43 to a time t65 corresponds to the readout period from the unit pixel 25(2, n). The readout of the signals from the photoelectric conversion elements PD1 to PD4 in the unit pixel 25(2, n) is performed during the period from the time t43 to the time t65. A period from the time t44 to the time t64 is a period in which the unit pixels 25 in the line including the unit pixel 25(2, n) are selected. The control signal SEL2 and the control signal SELB2 are fixed to the high level during the period from the time t44 to the time t64.

The potential of the high level is applied to the well W_{SEL} of the selection transistor M4 with the control signal SELBm at the timing when the selection transistor M4 is in the on state also in the third embodiment. This makes the well potential V_{B} in the on state of the selection transistor M4 relatively higher than the well potential V_{B} in the off state thereof. Since the effective threshold voltage V_{TH} is decreased when the well potential V_{B} is made high, the on resistance R_{ON} of the selection transistor M4 is decreased.

The decrease in the on resistance of the selection transistor M4 suppresses the reduction in the linearity to enable the acquisition of the high-quality image.

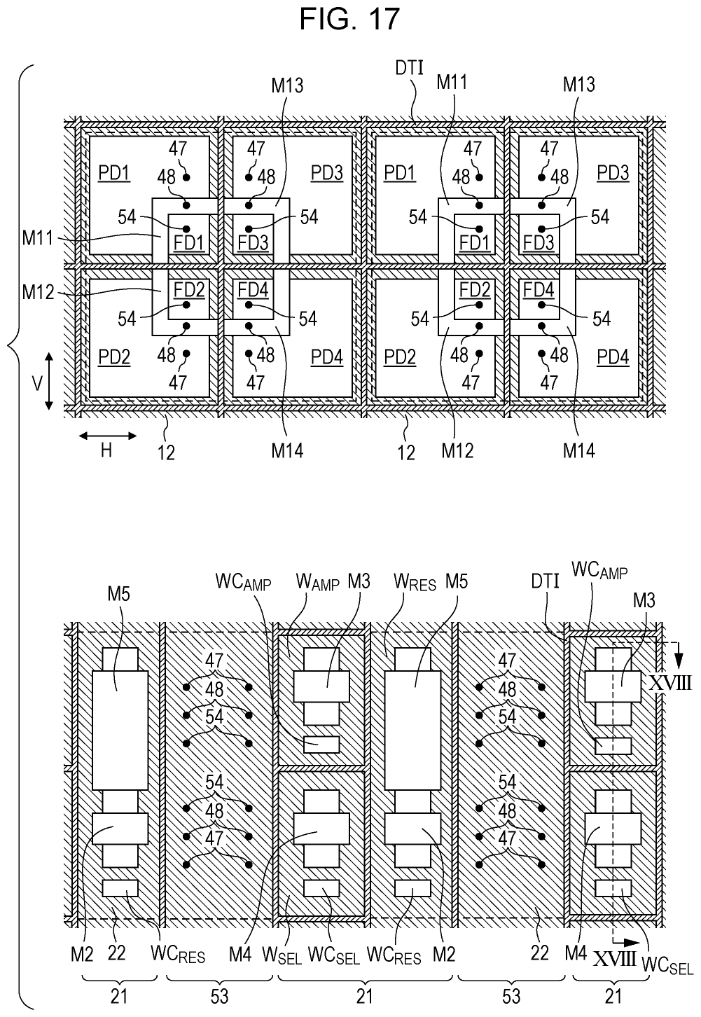

FIG. 17 illustrates a layout including the unit pixel 25D corresponding to the equivalent circuit diagram in FIG. 16 and illustrates the two unit pixels 25D of one line and two columns in a plan view. An upper diagram in FIG. 17 illustrates the layout of the first component 10 in FIG. 10 in a plan view. A lower diagram in FIG. 17 illustrates the layout of the second component 20 in FIG. 10 in a plan view.

The layout of the unit pixel 25D differs from the layout of the unit pixel 25C in that the amplifier transistor M3 is also surrounded by the insulating separator DTI. This causes the well W_{SEL}, the well W_{AMP}, and the well W_{RES} to be electrically separated from each other. The well W_{SEL} is a region including the region serving as the channel of the selection transistor M4. The well W_{AMP} is a region including the region serving as the channel of the amplifier transistor M3. The well W_{RES} is a region including regions serving as the channels of the reset transistor M2 and the FD capacitance switching transistor M5.

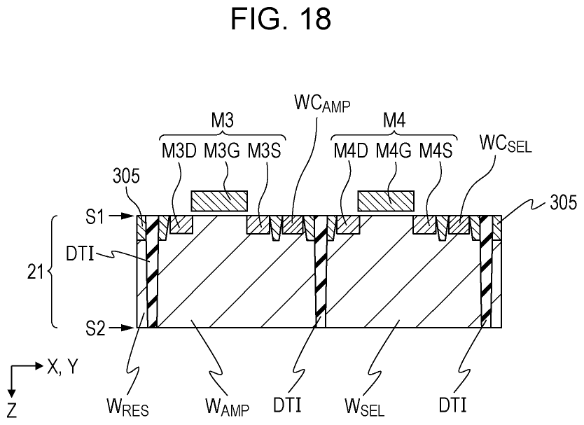

FIG. 18 is a schematic cross-sectional view taken along the XVIII-XVIII line in FIG. 17. The well W_{SEL} on which the selection transistor M4 is arranged, the well W_{AMP} on which the amplifier transistor M3 and so on are arranged, and the well W_{RES} on which the reset transistor M2 and the FD capacitance switching transistor M5 are arranged are electrically separated from each other with the insulating separator DTI.

Since the well W_{AMP} is physically separated from the well W_{SEL} and the well W_{RES} and the source of the amplifier transistor M3 is electrically connected to the well W_{AMP} in the unit pixel 25D, the voltage V_{BS} between the well and the source of the amplifier transistor is fixed to 0 V. Accordingly, the threshold voltage V_{TH} of the amplifier transistor M3 due to the substrate bias effect is capable of being kept constant. Consequently, the linear line of the signal is less likely to be non-linear, compared with a case in which the well potential V_{B} is connected to the ground potential.

As described above, in the unit pixel 25D, it is possible to suppress the reduction in the linearity of the signal due to the substrate bias effect of the amplifier transistor M3, in addition to the suppression of the reduction in the linearity by the selection transistor M4.

As described above, according to the third embodiment, the well W_{SEL} of the selection transistor M4 is separated from the wells on which the other pixel transistors are arranged and the potential of the well W_{SEL} is controlled in the on state and the off state of the selection transistor. Accordingly, it is possible to suppress the reduction in the linearity of the signal output from the unit pixel. In addition, it is possible to reduce the leakage current of the selection transistor.

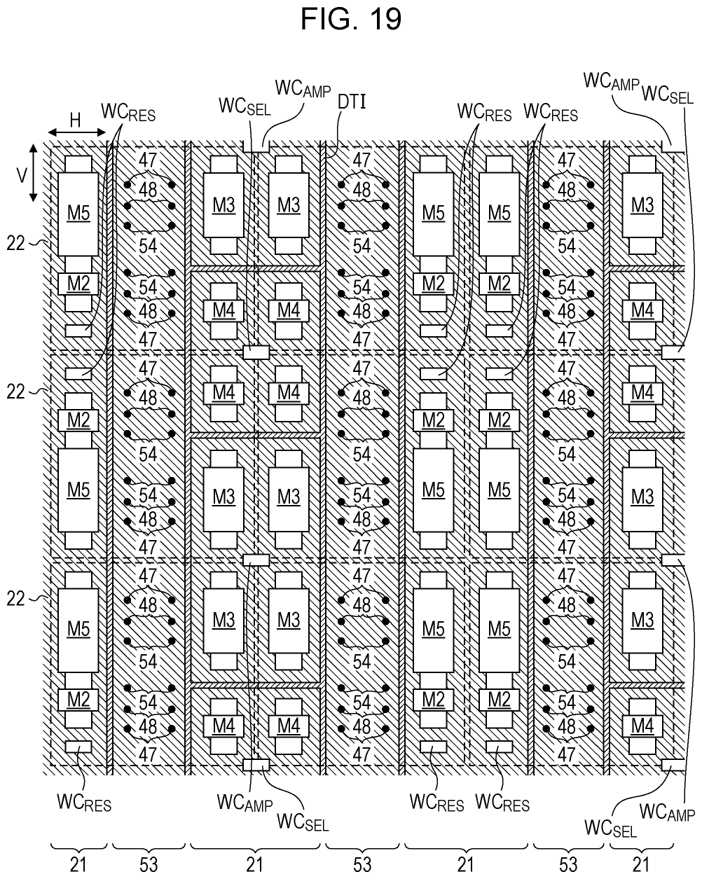

FIG. 19 illustrates the layout of the second component 20 including the unit pixel 25C corresponding to the equivalent circuit diagram in FIG. 11 and illustrates the nine unit pixels 25C of three lines and three columns in a plan view.

As illustrated in FIG. 19, the pixel transistors arranged in the read-out circuits 22 have the layout configuration sharing the wells of the same potential, which are adjacent in the horizontal direction and the vertical direction. More specifically, the well W_{SEL} of the selection transistor M4 and the well W_{AMP} of the amplifier transistor M3 are shared between the adjacent two lines and the adjacent two columns. The well W_{RES} is shared between the reset transistors M2 and the FD capacitance switching transistors M5 in the read-out circuits 22 adjacent in the vertical direction.

Sharing the wells of the same potential, which are adjacent in the horizontal direction and the vertical direction, enables the number of the well contacts arranged on the wells to be decreased to improve the layout efficiency. More specifically, one well contact WC_{AMP} is arranged for the well W_{AMP} of the four sharing amplifier transistors M3 and one well contact WC_{SEL} is arranged for the well W_{SEL} of the four sharing selection transistors M4. In addition, sharing the wells enables variation in the potential between the wells to be suppressed to realize the layout effective for the layout efficiency and the suppression of the variation in the potential.

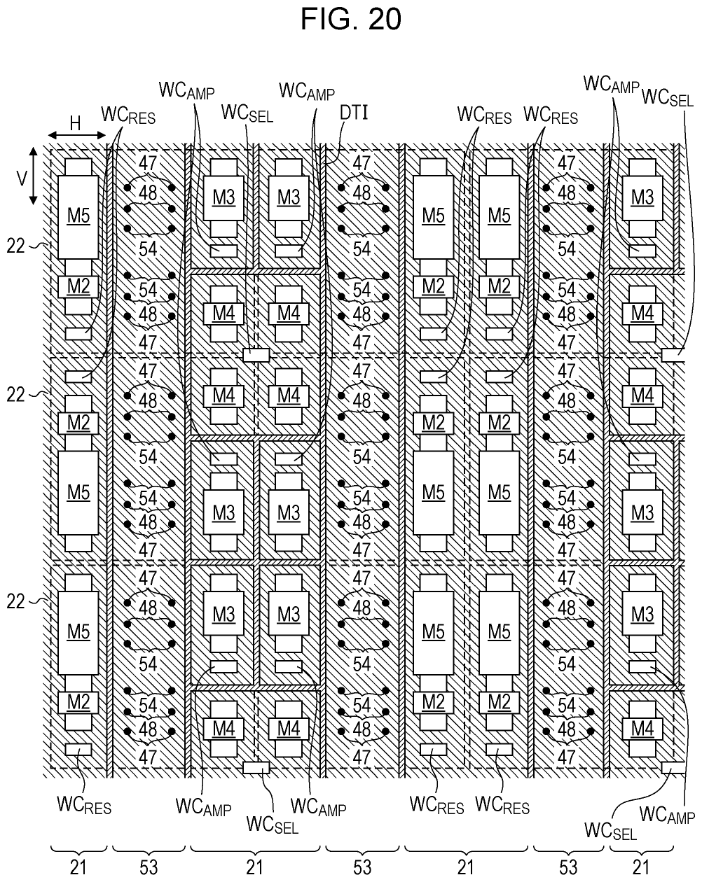

FIG. 20 illustrates the layout of the second component 20 including the unit pixel 25D corresponding to the equivalent circuit diagram in FIG. 16 and illustrates the nine unit pixels 25D of three lines and three columns in a plan view.

Sharing the wells of the same potential, which are adjacent in the horizontal direction and the vertical direction, realizes the layout effective for the layout efficiency and the suppression of the variation in the potential also in the layout configuration illustrated in FIG. 20, as in the layout configuration illustrated in FIG. 19.

The above embodiments are only specific examples to embody the disclosure and the technical range of the disclosure is not limitedly interrupted by the above embodiments. In other words, the disclosure is capable of being realized in various modes without departing from the technical scope or the main features of the disclosures.

### Fourth Embodiment

A fourth embodiment is applicable to the first to third embodiments.

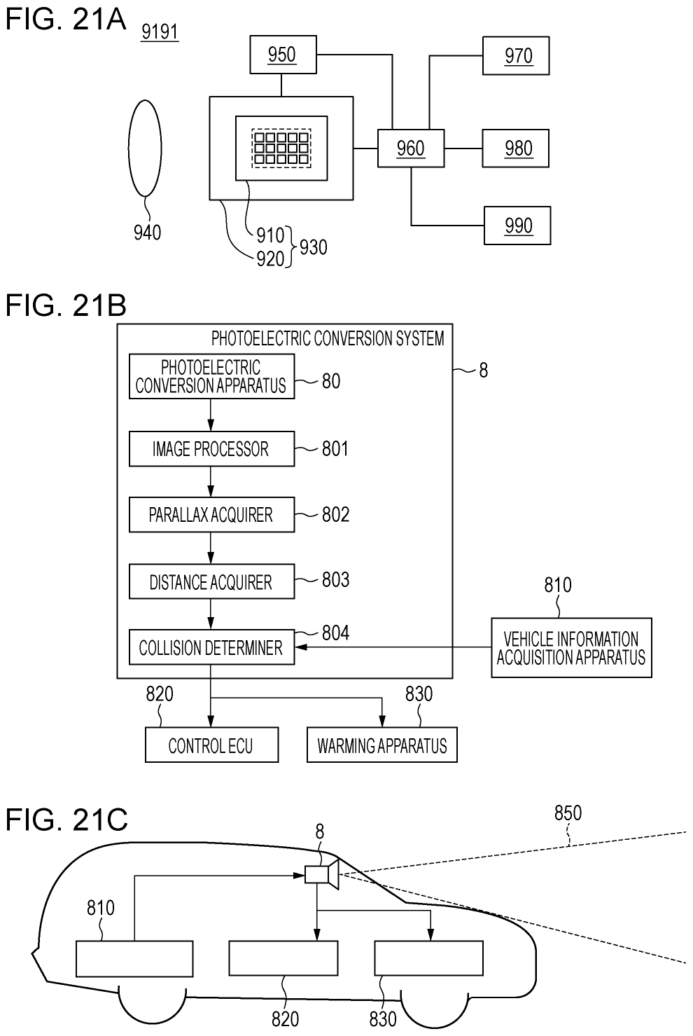

FIG. 21A is a schematic diagram for describing equipment 9191 including a photoelectric conversion apparatus 930 of the fourth embodiment. The photoelectric conversion apparatus 930 may be any of the photoelectric conversion apparatuses described in the first to third embodiments or may be a photoelectric conversion apparatus resulting from combination of multiple embodiments. The equipment 9191 including the photoelectric conversion apparatus 930 will now be described in detail. The photoelectric conversion apparatus 930 may include a semiconductor device 910 including a semiconductor layer and a package 920 containing the semiconductor device 910. The package 920 may include a base substrate to which the semiconductor device 910 is fixed and a cover body made of glass or the like, which is opposed to the semiconductor device 910. The package 920 may further include a joint member, such as boding wire or bumps, with which terminals provided on the base substrate are connected to terminals provided on the semiconductor device 910.

The equipment 9191 includes at least one of an optical apparatus 940, a control apparatus 950, a processing apparatus 960, a display apparatus 970, a storage apparatus 980, and a mechanical apparatus 990. The optical apparatus 940 corresponds to the photoelectric conversion apparatus 930. The optical apparatus 940 includes, for example, a lens, a shutter, or a mirror. The control apparatus 950 controls the photoelectric conversion apparatus 930. The control apparatus 950 is a control unit, such as an application specific integrated circuit (ASIC).

The processing apparatus 960 processes a signal output from the photoelectric conversion apparatus 930. The processing apparatus 960 is a semiconductor unit, such as a central processing unit (CPU) or the ASIC, for composing an analog front end (AFE) or a digital front end (DFE). The display apparatus 970 is an electroluminescence (EL) display or a liquid crystal display that displays information (an image) acquired by the photoelectric conversion apparatus 930.

The storage apparatus 980 is a magnetic device or a semiconductor device that stores the information (the image) acquired by the photoelectric conversion apparatus 930. The storage apparatus 980 is a volatile memory, such as a static random access memory (SRAM) or a dynamic RAM (DRAM), or a non-volatile memory, such as a flash memory or a hard disk drive.

The mechanical apparatus 990 includes a movable portion, such as a motor and/or an engine, or a propulsion portion. In the equipment 9191, the signal output from the photoelectric conversion apparatus 930 is displayed in the display apparatus 970 or is externally transmitted with a communication unit (not illustrated) provided in the equipment 9191. Accordingly, the equipment 9191 desirably further includes the storage apparatus 980 and the processing apparatus 960, in addition to a storage circuit and an operational circuit in the photoelectric conversion apparatus 930. The mechanical apparatus 990 may be controlled based on the signal output from the photoelectric conversion apparatus 930.

In addition, the equipment 9191 is appropriate for electronic equipment, such as an information terminal (for example, a smartphone or a wearable terminal) and a camera (for example, an interchangeable lens camera, a compact camera, a video camera, or a monitoring camera), which has an imaging function. The mechanical apparatus 990 in the camera is capable of driving components in the optical apparatus 940 for zooming, focusing, and a shutter operation. Alternatively, the mechanical apparatus 990 in the camera is capable of moving the photoelectric conversion apparatus 930 for an image stabilizing operation.

Furthermore, the equipment 9191 may be transport equipment, such as a vehicle, a ship, or a flight vehicle. The mechanical apparatus 990 in the transport equipment may be used as a moving apparatus. The equipment 9191 serving as the transport equipment is desirable for equipment that transports the photoelectric conversion apparatus 930 and equipment that performs assistance and/or automation of driving (steering) using the imaging function. The processing apparatus 960 for the assistance and/or the automation of driving (steering) is capable of performing a process to operate the mechanical apparatus 990 serving as the moving apparatus based on the information acquired by the photoelectric conversion apparatus 930. Alternatively, the equipment 9191 may be medical equipment such as an endoscope, measuring equipment such as a focusing sensor, analysis equipment such as an electronic microscope, a business machine such as a copier, or industrial equipment such as a robot.

According to the fourth embodiment described above, it is possible to achieve excellent pixel features. Accordingly, it is possible to improve the value of the photoelectric conversion apparatus. The improvement of the value here corresponds to at least one of addition of a function, improvement of performance, improvement of features, improvement of reliability, improvement of manufacturing yield, reduction in environmental load, reduction of cost, reduction of size, and weight saving.

Accordingly, the use of the photoelectric conversion apparatus 930 according to the fourth embodiment in the equipment 9191 enables the value of the equipment to be also improved. For example, it is possible to achieve the excellent performance when the photoelectric conversion apparatus 930 is mounted in transport equipment to perform imaging of the outside of the transport equipment or measurement of external environment. Consequently, the mounting of the photoelectric conversion apparatus according to the fourth embodiment in the transport equipment has an advantage in improvement of the performance of the transport equipment itself in manufacturing and selling of the transport equipment. In particular, the photoelectric conversion apparatus 930 is desirable for the transport equipment that performs operation support and/or automated driving of the transport equipment using the information acquired by the photoelectric conversion apparatus.

A photoelectric conversion system and a moving body of the fourth embodiment will now be described with reference to FIG. 21B and FIG. 21C.

FIG. 21B illustrates an example of the photoelectric conversion system concerning an in-vehicle camera. A photoelectric conversion system 8 includes a photoelectric conversion apparatus 80. The photoelectric conversion apparatus 80 is the photoelectric conversion apparatus (the imaging apparatus) described in any of the above embodiments. The photoelectric conversion system 8 includes an image processor 801 and a parallax acquirer 802. The image processor 801 performs image processing to multiple pieces of image data acquired by the photoelectric conversion apparatus 80. The parallax acquirer 802 calculates the parallax (the phase difference in a parallax image) from the multiple pieces of image data acquired by the photoelectric conversion system 8. The photoelectric conversion system 8 further includes a distance acquirer 803 and a collision determiner 804. The distance acquirer 803 calculates the distance to a target object based on the calculated parallax. The collision determiner 804 determines whether the possibility of collision exists based on the calculated distance. The parallax acquirer 802 and the distance acquirer 803 are examples of a distance information acquirer that acquires distance information to the target object. In other words, the distance information is information about the parallax, the amount of de-focusing, the distance to the target object, and so on. The collision determiner 804 may determine the possibility of collision using any distance information. The distance information acquirer may be realized by hardware that is designed for exclusive use or may be realized by a software module. Alternatively, the distance information acquirer may be realized by a field programmable gate array (FPGA), the ASIC, or the like or may be realized by combination of the above ones.

The photoelectric conversion system 8 is connected to a vehicle information acquisition apparatus 810 and is capable of acquiring vehicle information, such as a vehicle speed, a yaw rate, and a rudder angle. In addition, the photoelectric conversion system 8 is connected to a control electronic control unit (ECU) 820, which is a control unit that outputs a control signal to cause the vehicle to generate braking force based on the result of determination in the collision determiner 804. The photoelectric conversion system 8 is also connected to a warming apparatus 830 that issues a warning to a driver based on the result of determination in the collision determiner 804. For example, when the possibility of collision is high as the result of determination in the collision determiner 804, the control ECU 820 performs vehicle control to avoid the collision and reduce the damage by, for example, applying the brake to the vehicle, releasing the accelerator, or suppressing the engine output. The warming apparatus 830 issues the warning to a user by, for example, sounding an alarm, displaying warning information on the screen of a car navigation system or the like, vibrating the sheet belt or the steering.

In the fourth embodiment, an image of the circumference of the vehicle, for example, a forward image or a backward image of the vehicle is captured by the photoelectric conversion system 8.

FIG. 21C illustrates the photoelectric conversion system when a forward image of the vehicle (an image within an imaging range 850 ahead of the vehicle) is captured. The vehicle information acquisition apparatus 810 gives an instruction to the photoelectric conversion system 8 or the photoelectric conversion apparatus 80. With such a configuration, it is possible to improve the accuracy of the focusing.

Although the example is described above in which the control is performed so as not to collide with another vehicle, the photoelectric conversion system is applicable to control in which the automated driving is performed while tracking another vehicle, control in which the automated driving is performed so as not to run over the traffic lane, and so on. In addition, the photoelectric conversion system is not limited to the vehicle, such as a vehicle to be applied, and is applicable to a movable body (the moving apparatus), such as a ship, an aircraft, or an industrial robot. In addition, the photoelectric conversion system is not limited to the moving body and is applicable to equipment, such as an intelligent transport system (ITS), that widely uses object recognition.

The embodiments described above may be appropriately modified without departing from the technical idea. The content disclosed in the specification is not limited to the one described in the specification and includes all the matters capable of being understood from the specification and the drawings appended to the specification. The content disclosed in the specification includes complements of the ideas described in the specification. Specifically, for example, when “A is greater than B” is described in the specification, the specification discloses “A is not greater than B” even if description of “A is not greater than B” is omitted. This is because it is assumed that the case in which “A is not greater than B” is considered when “A is greater than B” is described.

With the technique in the disclosure, it is possible to appropriately set the potential of the well of the selection transistor.

While the present disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of priority from Japanese Patent Application No. 2022-165393, filed Oct. 14, 2022, which is hereby incorporated by reference herein in its entirety.

What is claimed is:

1. A photoelectric conversion apparatus comprising:
an output line; and
a plurality of unit pixels,
wherein each of the plurality of unit pixels includes
a photoelectric conversion element configured to generate signal electric charge based on incident light, and
a plurality of transistors, and
wherein the plurality of transistors at least includes
an amplifier transistor configured to have a gate into which the signal electric charge is input and to output a signal based on potential of the gate,
a selection transistor with which the amplifier transistor is connected to the output line, and
a reset transistor configured to reset the potential of the gate, the photoelectric conversion apparatus comprising:
a first well on which the selection transistor is provided; and
a second well on which at least two transistors in the plurality of transistors are provided,
wherein the first well is electrically separated from the second well.

2. The photoelectric conversion apparatus according to claim 1,
wherein the first well is electrically separated from the second well with an insulating separator, and
wherein the first well is surrounded by the insulating separator.

3. The photoelectric conversion apparatus according to claim 1,
wherein the selection transistor is an N-type transistor, and
wherein potential of the first well during a period in which the selection transistor is in an on state is higher than potential of the first well during a period in which the selection transistor is in an off state.

4. The photoelectric conversion apparatus according to claim 3,
wherein the potential of the first well during the period in which the selection transistor is in the on state is ground potential.

5. The photoelectric conversion apparatus according to claim 1,
wherein the selection transistor is a P-type transistor, and
wherein potential of the first well during a period in which the selection transistor is in an on state is lower than potential of the first well during a period in which the selection transistor is in an off state.

6. The photoelectric conversion apparatus according to claim 1,
wherein the selection transistor is an N-type transistor, and
wherein potential of the first well during a period in which the selection transistor is in an off state is lower than potential of the second well during the period.

7. The photoelectric conversion apparatus according to claim 6,
wherein the potential of the second well during the period is ground potential.

8. The photoelectric conversion apparatus according to claim 1,
wherein the selection transistor is an N-type transistor, and
wherein potential of the first well during a period in which the selection transistor is in an on state is higher than potential of the second well during the period.

9. The photoelectric conversion apparatus according to claim 1,
wherein the selection transistor is a P-type transistor, and
wherein potential of the first well during a period in which the selection transistor is in an on state is lower than potential of the second well during the period.

10. The photoelectric conversion apparatus according to claim 1,
wherein a transistor that switches between connection and non-connection of capacitance to the gate of the amplifier transistor is provided on the second well as one of the at least two transistors in the plurality of transistors.

11. The photoelectric conversion apparatus according to claim 10,
wherein the amplifier transistor is provided on the second well as one of the at least two transistors in the plurality of transistors.

12. The photoelectric conversion apparatus according to claim 10,
wherein the reset transistor is provided on the second well as one of the at least two transistors in the plurality of transistors.

13. The photoelectric conversion apparatus according to claim 11,
wherein the photoelectric conversion element is provided on the second well.

14. The photoelectric conversion apparatus according to claim 13,
wherein the reset transistor is provided on the second well as one of the at least two transistors in the plurality of transistors.

15. The photoelectric conversion apparatus according to claim 1,
wherein the amplifier transistor is provided on the second well as one of the at least two transistors in the plurality of transistors.

16. The photoelectric conversion apparatus according to claim 15,
wherein the reset transistor is provided on the second well as one of the at least two transistors in the plurality of transistors.

17. The photoelectric conversion apparatus according to claim 15,
wherein the photoelectric conversion element is provided on the second well.

18. The photoelectric conversion apparatus according to claim 1,
wherein the reset transistor is provided on the second well as one of the at least two transistors in the plurality of transistors.

19. The photoelectric conversion apparatus according to claim 1,
wherein the photoelectric conversion apparatus has a structure in which a first component is bonded to a second component,
wherein the photoelectric conversion element is arranged in the first component, and
wherein the first well and the second well are arranged in the second component.

20. The photoelectric conversion apparatus according to claim 19,
wherein the second component includes a semiconductor substrate, and
wherein the first component is electrically connected to the second component with a conductor that passes through an insulator that is provided from a first surface of the semiconductor substrate to a second surface opposed to the first surface.

21. The photoelectric conversion apparatus according to claim 19,
wherein the photoelectric conversion apparatus further includes a third component bonded to the second component, and
wherein the third component includes a logic circuit that processes a pixel signal based on a signal electric charge output from each of the plurality of unit pixels.

22. The photoelectric conversion apparatus according to claim 20,
wherein the photoelectric conversion apparatus further includes a third component bonded to the second component, and
wherein the third component includes a logic circuit that processes a pixel signal based on the signal electric charge output from each of the plurality of unit pixels.

23. Equipment including the photoelectric conversion apparatus according to claim 1, the equipment further comprising at least one of:
an optical apparatus corresponding to the photoelectric conversion apparatus;
a control apparatus configured to control the photoelectric conversion apparatus;
a processing apparatus configured to process a signal output from the photoelectric conversion apparatus;
a display apparatus configured to display information acquired by the photoelectric conversion apparatus;
a storage apparatus configured to store information acquired by the photoelectric conversion apparatus; and
a mechanical apparatus configured to operate based on information acquired by the photoelectric conversion apparatus.

24. A method of driving a photoelectric conversion apparatus comprising:
an output line; and
a plurality of unit pixels,
wherein each of the plurality of unit pixels includes
a photoelectric conversion element configured to generate signal electric charge based on incident light, and
a plurality of transistors, and
wherein the plurality of transistors at least includes
an amplifier transistor configured to have a gate into which the signal electric charge is input and to output a signal based on potential of the gate,
a selection transistor with which the amplifier transistor is connected to the output line, and
a reset transistor configured to reset the potential of the gate, the photoelectric conversion apparatus comprising:
a first well on which the selection transistor is provided; and
a second well on which at least two transistors in the plurality of transistors are provided, the method comprising:
setting potential of the second well to first potential during a period in which the selection transistor is in an off state; and
setting the potential of the second well to second potential different from the first potential during a period in which the selection transistor is in an on state.

25. A semiconductor substrate laminated on a component in which a photoelectric conversion element that generates signal electric charge based on incident light is provided, the semiconductor substrate comprising:
an output line; and
a plurality of transistors,
wherein the plurality of transistors at least includes
an amplifier transistor configured to have a gate into which the signal electric charge is input and to output a signal based on potential of the gate,
a selection transistor with which the amplifier transistor is connected to the output line, and
a reset transistor configured to reset the potential of the gate, the semiconductor substrate comprising:
a first well on which the selection transistor is provided; and
a second well on which at least two transistors in the plurality of transistors are provided,
wherein the first well is electrically separated from the second well.
